(19) United States
(12) Patent Application Publication
(10) Pub. No.: US 2024/0249056 A1
(43) Pub. Date: Jul. 25, 2024

(54) ENGINEERING CHANGE ORDER (ECO) SPARE CELL

(71) Applicant: QUALCOMM Incorporated, San Diego, CA (US)

(72) Inventors: Hyeokjin LIM, San Diego, CA (US); Ankur MEHROTRA, Greater Noida (IN); Renukprasad HIREMATH, Hillsboro, OR (US); Foua VANG, Sacramento, CA (US); Manjanaika CHANDRANAIKA, Bangalore (IN); Akhtar ALAM, Bangalore (IN); Kamesh MEDISETTI, Bangalore (IN); Seung Hyuk KANG, San Diego, CA (US); Venugopal BOYNAPALLI, San Diego, CA (US)

(21) Appl. No.: 18/156,999

(22) Filed: Jan. 19, 2023

(51) Int. Cl. G06F 30/392; H01L 21/768; H01L 23/48; H01L 23/498; H01L 23/528; H01L 27/02

(52) U.S. Cl. CPC G06F 30/392; H01L 21/76898; H01L 23/481; H01L 23/49827; H01L 23/5286; H01L 27/0207

(57) ABSTRACT

A chip includes a spare cell including a first active region, and a first gate extending over the first active region in a first direction. The chip also includes a tie cell including a second active region, a second gate extending over the second active region in the first direction, a first drain contact formed over the second active region, a first source contact formed over the second active region, wherein the second gate is between the first drain contact and the first source contact, and first source contact is coupled to a first rail, and a circuit configured to couple the second gate to a second rail. The chip also includes a metal routing extending in a second direction, wherein the second direction is perpendicular to the first direction, and the first metal routing is coupled to the first drain contact and the first gate.

### BACKGROUND

### Field

Aspects of the present disclosure relate generally to integrated circuit layout, and, more particularly, to engineer change order (ECO) spare cells.

### Background

A chip (i.e., die) may include many cells (e.g., thousands to millions of cells) laid out on the chip. Each cell includes one or more transistors that are arranged to provide a logic gate (e.g., an inverter, NAND gate, NOR gate, etc.), a latch, a flip-flop, a buffer, and/or another circuit (e.g., a circuit configured to perform a basic function). The layout of each cell may be specified by a standard cell library that defines the layouts for various types of cells that can be placed on the chip. The chip may also include metal routing (also referred to as metal interconnects) for interconnecting cells to form larger circuits.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a spare cell including a first active region, and a first gate extending over the first active region in a first direction. The chip also includes a tie cell including a second active region, a second gate extending over the second active region in the first direction, a first drain contact formed over the second active region, a first source contact formed over the second active region, wherein the second gate is between the first drain contact and the first source contact, and first source contact is coupled to a first rail, and a circuit configured to couple the second gate to a second rail. The chip also includes a metal routing extending in a second direction, wherein the second direction is perpendicular to the first direction, and the first metal routing is coupled to the first drain contact and the first gate.

A second aspect relates to a chip. The chip includes a first spare cell including a first active region, and a first gate extending over the first active region in a first direction. The chip also includes a second spare cell including a second active region, and a second gate extending over the second active region in the first direction. The chip also includes a tie cell including a third active region, a third gate extending over the third active region in the first direction, a first drain contact formed over the third active region, a first source contact formed over the third active region, wherein the third gate is between the first drain contact and the first source contact, and the first source contact is coupled to a first rail, and a circuit configured to couple the third gate to a second rail. The chip also includes a metal routing extending in a second direction, wherein the second direction is perpendicular to the first direction, and the first metal routing is coupled to the first drain contact, the first gate, and the second gate.

A third aspect relates to a method for chip layout. The method includes receiving a layout for a chip, wherein the layout includes a metal routing coupling an input of a spare cell to a tie cell on the chip, determining whether to use the spare cell to implement a circuit design on a chip, and, if a determination is made to use the spare cell to implement the circuit design, then inserting a cut layer in the layout for cutting the metal routing between the input of the spare cell and the tie cell.

### BRIEF DESCRIPTION OF THE DRAWINGS

FIG. 1 shows an exemplary layout of a spare cell and a tie cell according to certain aspects of the present disclosure.

FIG. 2 shows an exemplary layout of vias on the spare cell and the tie cell according to certain aspects of the present disclosure.

FIG. 3A shows an exemplary layout of metal routing for a case where the spare cell is inactive according to certain aspects of the present disclosure.

FIG. 3B shows an exemplary layout of metal routing for a case where the spare cell is active to certain aspects of the present disclosure.

FIG. 4A shows an exemplary circuit diagram of the spare cell and the tie cell for the case where the spare cell is inactive according to certain aspects of the present disclosure.

FIG. 4B shows an exemplary circuit diagram of the spare cell and the tie cell for the case where the spare cell is active according to certain aspects of the present disclosure.

FIG. 5 shows another exemplary layout of a spare cell and a tie cell according to certain aspects of the present disclosure.

FIG. 6A shows another exemplary layout of metal routing for a case where the spare cell is inactive according to certain aspects of the present disclosure.

FIG. 6B shows another exemplary layout of metal routing for a case where the spare cell is active to certain aspects of the present disclosure.

FIG. 7A shows another exemplary circuit diagram of the spare cell and the tie cell for the case where the spare cell is inactive according to certain aspects of the present disclosure.

FIG. 7B shows another exemplary circuit diagram of the spare cell and the tie cell for the case where the spare cell is active according to certain aspects of the present disclosure.

FIG. 8 shows yet another exemplary layout of a spare cell and a tie cell according to certain aspects of the present disclosure.

FIG. 9 shows another exemplary layout of vias on the spare cell and the tie cell according to certain aspects of the present disclosure.

FIG. 10 shows an exemplary layout of metal routing over the spare cell and the tie cell according to certain aspects of the present disclosure.

FIG. 11 shows an exemplary layout of vias on the metal routing according to certain aspects of the present disclosure.

FIG. 12A shows yet another exemplary layout of metal routing for a case where the spare cell is inactive according to certain aspects of the present disclosure.

FIG. 12B shows yet another exemplary layout of metal routing for a case where the spare cell is active to certain aspects of the present disclosure.

FIG. 13A shows yet another exemplary circuit diagram of the spare cell and the tie cell for the case where the spare cell is inactive according to certain aspects of the present disclosure.

FIG. 13B shows yet another exemplary circuit diagram of the spare cell and the tie cell for the case where the spare cell is active according to certain aspects of the present disclosure.

FIG. 14A shows an example of a tie cell coupled to a first spare cell and a second spare cell according to certain aspects of the present disclosure.

FIG. 14B shows an example in which the first spare cell is active and the second spare cell is inactive according to certain aspects of the present disclosure.

FIG. 14C shows an example in which the first spare cell is inactive and the second spare cell is active according to certain aspects of the present disclosure.

FIG. 14D shows an example in which the first spare cell and the second spare cell are both active according to certain aspects of the present disclosure.

FIG. 15 is a block diagram illustrating a computer system according to certain aspects of the present disclosure.

FIG. 16 is a flowchart illustrating a method for chip layout according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

A chip (i.e., die) may include many cells (e.g., thousands to millions of cells) laid out on the chip. Each cell includes one or more transistors that are arranged to provide a logic gate (e.g., an inverter, NAND gate, NOR gate, etc.), a latch, a flip-flop, a buffer, and/or another circuit (e.g., a circuit configured to perform a basic function). The layout of each cell may be specified by a standard cell library that defines the layouts for various types of cells that can be placed on the chip. The layout of each cell may include the layout of various structures of the one or more transistors in the cell including, for example, the layout of gates (e.g., poly gates), active regions (e.g., oxide diffusion (OD) regions), contacts, etc. The layout of the cells on the chip is specified in a base tape out (BTO) layer. After the BTO layer, the layout of the cells on the chip may be fixed.

The chip may also include metal routing (also referred to as metal interconnects) for interconnecting cells on the chip to form larger circuits. The metal routing may be formed from a stack of metal layers over the cells. The metal layers may also be referred to as metallization layers, or another term. The bottom-most metal layer in the stack may be designated metal layer M0 (also referred to as metal 0), the metal layer in the stack immediately above metal layer M0 may be designated metal layer M1 (also referred to as metal 1), and so forth. During processing, the metal layers (e.g., M0, M1, etc.) are patterned (e.g., using photolithography and etching) to form the metal routing (i.e., metal interconnects). The layout of the metal routing on the chip is specified in a metal tape out (MTO) layer. As discussed further below, the MTO layer allows changes in the metal routing after the layout of the cells is fixed in the BTO layer.

The chip may also include spare cells to facilitate engineering change order (ECO) after the BTO layer. ECO may be used to make changes to the design of circuits on the chip after the BTO layer by changing the layout of metal routing interconnecting the cells in the MTO layer. In other words, changes to the design of circuits on the chip may be made after the BTO layer using the MTO layer. Using the MTO layout to make circuit design changes reduces cost and development time by not requiring changes in the BTO layer. The circuit design changes may be made, for example, to add more functionality to a circuit, fix a flaw in the design of a circuit, fix a timing issue in a circuit, etc.

The spare cells may be distributed (i.e., sprinkled) throughout the chip. Each spare cell may include one or more transistors that are arranged to provide a logic gate (e.g., an inverter, NAND gate, NOR gate, etc.), a latch, a flip-flop, a buffer, and/or another circuit (e.g., a circuit configured to perform a basic function). The spare cells provide additional cells on the chip that may be utilized to implement changes in the design of circuits on the chip after the BTO layer. For example, if a change in the design of a circuit requires one or more additional cells, then one or more spare cells may be added to the circuit to implement the change. In this case, the layout of metal routing in the MTO layer may be changed to couple the one or more spare cells to other cells in the circuit.

In certain aspects, a spare cell may be inactive or active on the chip depending on whether the spare cell is needed to implement a circuit design change. The spare cell is inactive when the spare cell is not used in a circuit on the chip to perform a function (e.g., logic function). The spare cell is active when the spare cell is used in a circuit on the chip to perform a function. For example, the spare cell may be made active when the spare cell is needed to implement a circuit design change. In this case, the layout of metal routing in the MTO layer is changed to couple the spare cell to other cells in the circuit (i.e., to incorporate the spare cell into the circuit).

In one approach, when a spare cell is inactive, the input of the spare cell is left floating. A problem with this approach is that the input of the spare cell may float to a potential that causes the spare cell to conduct and leak a relatively large amount of current. The leakage current wastes power since the spare cell does not perform a useful function in this case.

To reduce the leakage current from a spare cell that is inactive, the spare cell may be decoupled from a supply rail and/or a low rail (e.g., ground rail) in the MTO layer. The supply rail provides a supply voltage VDD (e.g., from a power distribution network) and the low rail has a voltage VSS (e.g., ground) that is below the supply voltage. In other words, the low rail has a lower potential than the supply rail. The supply rail and the low rail are formed from one or more of the metal layers (e.g., metal layer M0) in the MTO layer. In this approach, the spare cell is decoupled from the supply rail and/or the low rail by cutting the supply rail and/or the low rail from the spare cell in the MTO layer.

However, as geometries continue to scale down in advanced process nodes, design rule restrictions become tighter. Because of the tighter restrictions in advanced process node, it may no longer be possible to cut the supply rail and/or the low rail from the spare cell in the MTO layer to reduce leakage current when the spare cell is inactive. Accordingly, another approach for reducing the leakage current of an inactive spare cell in the MTO layer is desirable.

To address the above, aspects of the present disclose provide a tie cell for reducing leakage current when a spare cell is inactive. To make the spare cell inactive, an input of the spare cell is coupled to the tie cell by metal routing formed from a metal layer (e.g., metal layer M0) in the MTO layer. In this case, the tie cell is configured to tie the input of the spare cell to VDD or VSS instead of allowing the potential of the input to float, which helps prevent the spare cell from conducting current and therefore reduces leakage current. To make the spare cell active (e.g., to implement a circuit design change), the spare cell is decoupled from the tie cell (e.g., by cutting the metal routing coupling the input of the spare cell to the tie cell). The above features and other features of the present disclosure are discussed further below.

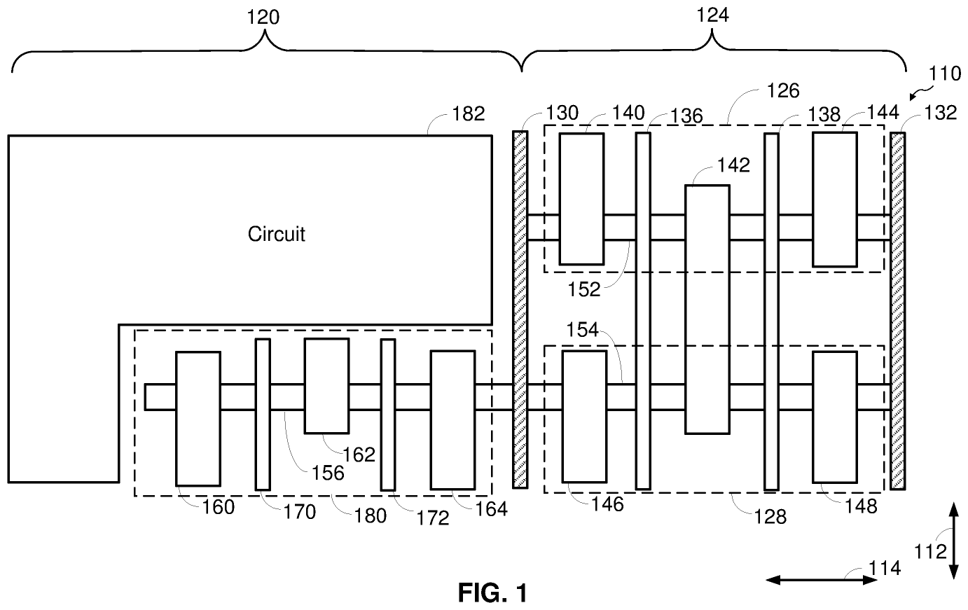

FIG. 1 shows a top view of an example of a spare cell 124 and a tie cell 120 according to certain aspects. In this example, the spare cell 124 is configured to perform an inverting function when the spare cell is active. However, it is to be appreciated that the spare cell 124 is not limited to this example, and that the spare cell 124 may be configured to perform another function.

In this example, the chip includes a first dummy gate 130 and a second dummy gate 132. The first dummy gate 130 may provide a boundary between the tie cell 120 and the spare cell 124 in the BTO layer, and the second dummy gate 132 may provide a boundary between the spare cell 124 and a neighboring cell (not shown) in the BTO layer. The first dummy gate 130 may be implemented with a first poly over diffusion edge (PODE), and the second dummy gate 132 may be implemented with a second PODE. However, it is to be understood that the first dummy gate 130 and the second dummy gate 132 are not limited to this example. It is to be appreciated that a “dummy gate” is not used as a gate of a transistor. In the example shown in FIG. 1, each of the dummy gates 130 and 132 is elongated and extends in lateral direction 112. As used herein, a “lateral direction” is a direction that runs parallel with the substrate 110 of the chip.

In this example, the spare cell 124 includes a first transistor 126 and a second transistor 128. The first transistor 126 may be a p-type field effect transistor (PFET) and the second transistor 128 may be an n-type field effect transistor (NFET) (e.g., to implement a complementary inverter). However, it is to be appreciated that the present disclosure in not limited to this example. FIG. 1 shows an exemplary layout for the first transistor 126 and the second transistor 128, which is discussed further below.

In the example in FIG. 1, the spare cell 124 includes a first active region 152 (e.g., first oxide diffusion (OD)). The first active region 152 extends in lateral direction 114 between the first dummy gate 130 and the second dummy gate 132, in which lateral direction 114 is perpendicular to lateral direction 112. In this example, the first active region 152 may be a p-type active region (e.g., OD) that is formed using p+ diffusion, p+ implantation, or another process. For an example of a fin field-effect transistor (FinFET) process, the first active region 152 may include one or more fins extending in lateral direction 114.

The spare cell 124 also includes a second active region 154 (e.g., second oxide diffusion (OD)). The second active region 154 extends in lateral direction 114 between the first dummy gate 130 and the second dummy gate 132, and is separated from the first active region 152 in lateral direction 112. In this example, the second active region 154 may be an n-type active region (e.g., OD) that is formed using n+ diffusion, n+ implantation, or another process. For the example of a FinFET process, the second active region 154 may include one or more fins extending in lateral direction 114.

The spare cell 124 also includes a first gate 136 and a second gate 138. The first gate 136 and the second gate 138 may each be a poly-silicon gate, a metal gate, or another type of gate. Each of the first gate 136 and the second gate 138 is elongated and extends in lateral direction 112 over the first active region 152 and the second active region 154, as shown in FIG. 1. The first gate 136 and the second gate 138 are separated from each other in lateral direction 114. Portions of the first active region 152 under the first gate 136 and the second gate 138 form the channel of the first transistor 126 (e.g., PFET), and portions of the second active region 154 under the first gate 136 and the second gate 138 form the channel of the second transistor 128 (e.g., NFET).

In the example shown in FIG. 1, each of the transistors 126 and 128 is a two-gate transistor (i.e., two-finger transistor) including two gates (e.g., the first gate 136 and the second gate 138). However, it is to be appreciated that the present disclosure is not limited to this example. For example, in other implementations, each of the transistors 126 and 128 may include a single gate in which one of the gates 136 and 138 is omitted, or each of the transistors 126 and 128 may include three or more gates including the gates 136 and 138 and one or more additional gates.

In the example in FIG. 1, the first gate 136 and the second gate 138 provide the gate of the first transistor 126 and the gate of the second transistor 128. Thus, in this example, the first gate 136 and the second gate 138 are shared by the first transistor 126 and the second transistor 128. This is because the gate of the first transistor 126 and the gate of the second transistor 128 are coupled together to provide an input of an inverter (e.g., complementary inverter) in this example. However, it is to be appreciated that the present disclosure is not limited to this example.

In the example in FIG. 1, the spare cell 124 further includes a first source/drain contact 140, a second source/drain contact 142, a third source/drain contact 144, a fourth source/drain contact 146, and a fifth source/drain contact 148. As used herein, the term “source/drain” means source and/or drain. The source/drain contacts 140, 142, 144, 146, and 148 may be formed from a source/drain contact layer using, for example, a photolithographic process and an etching process. The source/drain contact layer may also be referred to as a metal diffusion (MD) layer, or another term. The source/drain contact layer may include one or more metals and/or one or more other electrically conductive materials.

In the example in FIG. 1, the first source/drain contact 140 is disposed over a portion of the first active region 152 between the first dummy gate 130 and the first gate 136, the second source/drain contact 142 is disposed over a portion of the first active region 152 between the first gate 136 and the second gate 138, and the third source/drain contact 144 is disposed over a portion of the first active region 152 between the second gate 138 and the second dummy gate 132. In this example, the first source/drain contact 140 and the third source/drain contact 144 may each provide a source contact for the first transistor 126, and the second source/drain contact 142 may provide a drain contact for the first transistor 126.

In the example in FIG. 1, the fourth source/drain contact 146 is disposed over a portion of the second active region 154 between the first dummy gate 130 and the first gate 136, the fifth source/drain contact 148 is disposed over a portion of the second active region 154 between the second gate 138 and the second dummy gate 132, and the second source/drain contact 142 is disposed over a portion of the second active region 154 between the first gate 136 and the second gate 138. In this example, the fourth source/drain contact 146 and the fifth source/drain contact 148 may each provide a source contact for the second transistor 128, and the second source/drain contact 142 may provide a drain contact for the second transistor 128.

In the example in FIG. 1, the second source/drain contact 142 is shared by the first transistor 126 and the second transistor 128. This is because the drain of the first transistor 126 and the drain of the second transistor 128 are coupled together to provide an output of the inverter (e.g., complementary inverter) in this example. However, it is to be appreciated that the present disclosure is not limited to this example.

It is to be appreciated that the spare cell 124 is not limited to the exemplary layout shown in FIG. 1. For example, is some implementations, each of the transistors 126 and 128 may be implemented with a single-gate transistor. In these implementations, one of the gates 136 and 138 may be omitted, one of the first and third source/drain contacts 140 and 144 may be omitted, and one of the fourth and fifth source/drain contacts 146 and 148 may be omitted. It is also to be appreciated that the layout may include one or more additional structures not shown in FIG. 1 (e.g., an N-well for the first active region 152, one or more additional gates, one or more additional source/drain contacts, and/or any combination thereof).

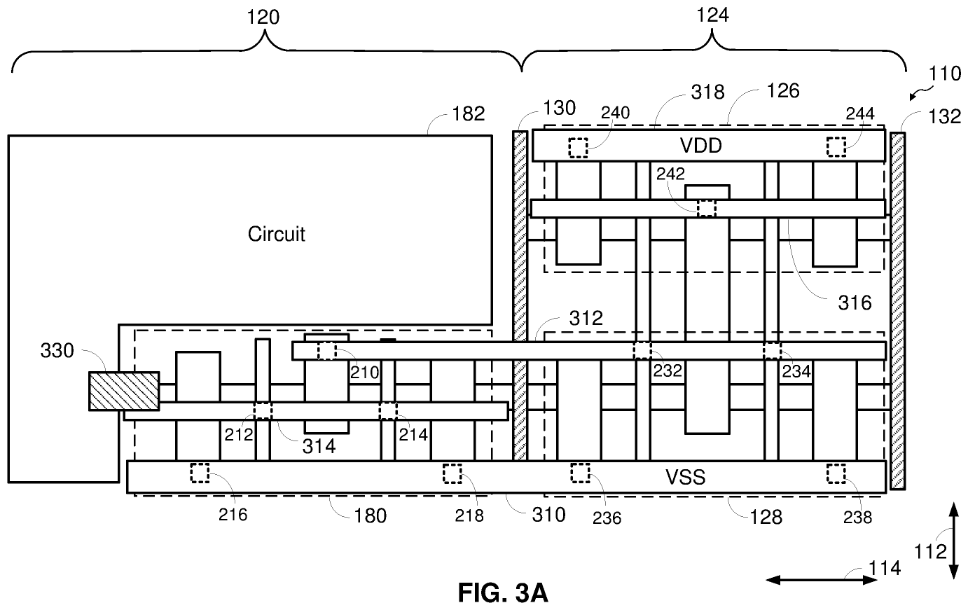

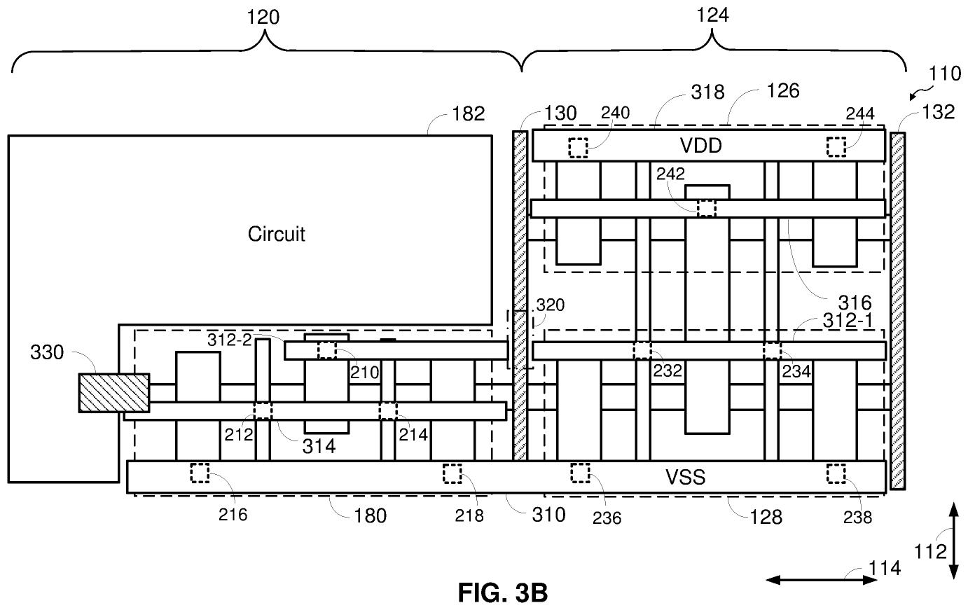

In the example in FIG. 1, the tie cell 120 includes a transistor 180 and a circuit 182 according to certain aspects. The transistor 180 is configured to tie the input of the spare cell 124 to VSS (i.e., a low rail) when the spare cell is inactive. In the example in FIG. 1, the input of the spare cell 124 corresponds to the first and second gates 136 and 138, which provide the input of the inverter in the spare cell 124 in this example. However, it is to be appreciated that the input of the spare cell 124 is not limited to this example. As discussed further below, when the spare cell 124 is inactive, the transistor 180 is coupled to the input of the spare cell 124 via a metal routing (shown in FIG. 3A) in the MTO layer. When the spare cell 124 is active, the metal routing is cut to decouple the spare cell 124 from the tie cell 120. The circuit 182 is coupled to the gate of the transistor 180 and configured to turn on the transistor 180, as discussed further below.

In the example in FIG. 1, the tie cell 120 includes an active region 156 (e.g., OD) extending in lateral direction 114. In certain aspect, the active region 156 in the tie cell 120 and the second active region 154 in the spare cell 124 may be formed from a longer active region that is cut under the first dummy gate 130 to form the active regions 154 and 156. The active region 156 may be an n-type active region (e.g., OD) that is formed using n+ diffusion, n+ implantation, or another process. For the example of the FinFET process, the active region 156 may include one or more fins extending in lateral direction 114.

In this example, the tie cell 120 includes a first gate 170 and a second gate 172 extending over the active region 156 in lateral direction 112. The first gate 170 and the second gate 172 are separated from each other in lateral direction 114. Portions of the active region 156 under the first gate 170 and the second gate 172 form the channel of the transistor 180 (e.g., NFET). In the example shown in FIG. 1, the transistor 180 is a two-gate transistor (i.e., two-finger transistor) including the first gate 170 and the second gate 172. However, it is to be appreciated that the present disclosure is not limited to this example. For example, in other implementations, the transistor 180 may be a single-gate transistor in which one of the gates 170 and 172 is omitted, or the transistor 180 may include three or more gates including the gates 170 and 172 and one or more additional gates. In the example in FIG. 1, the first gate 170 and the second gate 172 provide the gate of the transistor 180.

In the example in FIG. 1, the tie cell 120 further includes a first source/drain contact 160, a second source/drain contact 162, and a third source/drain contact 164. The source/drain contacts 160, 162, and 164 may be formed from the source/drain contact layer discussed above using, for example, a photolithographic process and an etching process.

In the example in FIG. 1, the first source/drain contact 160 is disposed over a portion of the active region 156 between the circuit 182 and the first gate 170, the second source/drain contact 162 is disposed over a portion of the active region 156 between the first gate 170 and the second gate 172, and the third source/drain contact 164 is disposed over a portion of the active region 156 between the second gate 172 and the first dummy gate 130. In this example, the first source/drain contact 160 and the third source/drain contact 164 may each provide a source contact for the transistor 180, and the second source/drain contact 162 may provide a drain contact for the transistor 180.

As discussed above, the circuit 182 is configured to turn on the transistor 180 to allow the transistor 180 to tie the input of the spare cell 124 to VSS when the spare cell 124 is inactive. The circuit 182 may be implemented with one or more transistors (not shown in FIG. 1) that are configured to turn on the transistor 180. For example, the circuit 182 may be configured to tie the gate of the transistor 180 to VDD (i.e., supply rail) to turn on the transistor 180. An exemplary implementation of the circuit 182 is discussed further below.

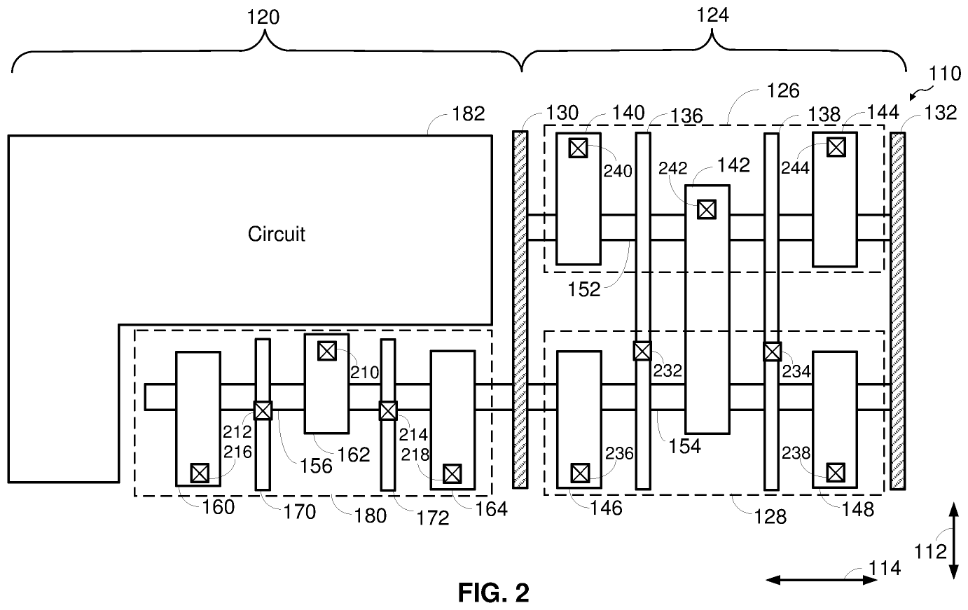

FIG. 2 shows an example of vias used to couple various structures of the spare cell 124 and the tie cell 120 to metal routing (shown in FIGS. 3A and 3B). In this example, the chip includes a gate via 232 disposed on the first gate 136 and a gate via 234 disposed on the second gate 138 in the spare cell 124. The gate vias 232 and 234 may be aligned in lateral direction 112, as shown in FIG. 2. It is to be appreciated that, in some implementations, gate contacts (not shown in FIG. 2) may be disposed between the gates 136 and 138 and the respective gate vias 232 and 234. A gate via may also be referred to as a VG via.

The chip may also include a via 240 disposed on the first source/drain contact 140, a via 242 disposed on the second source/drain contact 142, a via 244 disposed on the third source/drain contact 144, a via 236 disposed on the fourth source/drain contact 146, and a via 238 disposed on the fifth source/drain contact 148 in the spare cell 124. It is to be appreciated that the vias 236, 238, 240, 242, and 244 are not limited to the exemplary shapes shown in FIG. 2. For example, in some implementations, one or more of the vias 236, 238, 240, 242, and 244 may have a rectangular shape or another shape. It is also to be appreciated that the vias 236, 238, 240, 242, and 244 do not need to all have the same shape.

In this example, the chip also includes a gate via 212 disposed on the first gate 170 and a gate via 214 disposed on the second gate 172 in the tie cell 120. The gate vias 212 and 214 may be aligned in lateral direction 112, as shown in FIG. 2. It is to be appreciated that, in some implementations, gate contacts (not shown in FIG. 2) may be disposed between the gates 170 and 172 and the respective gate vias 212 and 214.

The chip may also include a via 216 disposed on the first source/drain contact 160, a via 210 disposed on the second source/drain contact 162, and via 218 disposed on the third source/drain contact 164 in the tie cell 120. It is to be appreciated that the vias 210, 212, 214, 216, and 218 are not limited to the exemplary shapes shown in FIG. 2.

In the example shown in FIG. 2, the via 210 on the second source/drain contact 162 in the tie cell 120 is aligned with the gate vias 232 and 234 in the spare cell 124 in the lateral direction 112. As discussed further below, this allows the drain of the transistor 180 to be coupled to the input of the spare cell 124 by a metal routing extending in lateral direction 114 from the via 210 to the gate vias 232 and 234.

In certain aspects, the exemplary layout shown FIG. 2 may be fixed. In these aspects, the spare cell 124 may be made inactive or active using the MTO layer, as discussed further below.

FIG. 3A shows an example of a layout of metal routing over the spare cell 124 and the tie cell 120 for a case where the spare cell 124 is inactive according to certain aspects. The metal routing shown in FIG. 3A may be formed from a metal layer (e.g., metal layer M0) in the MTO layer (e.g., using photolithography and etching). For ease of illustration, the reference numbers of some of the structures in the tie cell 120 and the spare cell 124 are omitted in FIG. 3A.

In this example, the chip includes a first metal routing 312 coupled to the via 210 in the tie cell 120 and the gate vias 232 and 234 in the spare cell 124. The vias 210 and the gate vias 232 and 234 are shown with dotted lines in FIG. 3A to indicate that the vias 210 and the gate vias 232 and 234 are below the first metal routing 312. The first metal routing 312 is elongated and extends in lateral direction 114 from the vias 210 in the tie cell 120 to gate vias 232 and 234 in the spare cell 124. In the example in FIG. 3A, the first metal routing crosses over the first dummy gate 130 between the tie cell 120 and the spare cell 124. In certain aspects, the first metal routing 312 is a metal line extending from vias 210 in the tie cell 120 to gate vias 232 and 234 in the spare cell 124, in which the metal line is patterned from a metal layer (e.g., metal layer M0) in the MTO layer.

FIG. 3A shows the first metal routing 312 for the case where the spare cell 124 is inactive. In this case, the first metal routing 312 couples the input of the spare cell 124 to the transistor 180 in the tie cell 120. More particularly, in the example in FIG. 3A, the first metal routing 312 couples the gates 136 and 138 of the first and second transistors 126 and 128 in the spare cell 124 to the drain of the transistor 180 in the tie cell 120. As discussed further below, the transistor 180 ties the input of the spare cell 124 to VSS, which helps prevent current from flowing through the spare cell 124 and therefore reduce leakage current.

The chip also includes a second metal routing 314 that extends in lateral direction 114. The second metal routing 314 is coupled to the gate vias 212 and 214 in the tie cell 120. The gate vias 212 and 214 are shown with dotted lines in FIG. 3A to indicate that the gate vias 212 and 214 are below the second metal routing 314.

In this example, the chip also includes an interconnect 330 coupling the second metal routing 314 to the circuit 182. The interconnect 330 may include one or more vias and metal routing formed from one or more metal layers (e.g., metal layer M1). Note that a layout of the interconnect 330 is not shown in detail in FIG. 3A. An exemplary layout for the interconnect 330 is discussed further below. The second metal routing 314 and the interconnect 330 couple the circuit 182 to the gate of the transistor 180.

In certain aspects, the circuit 182 is configured to turn on the transistor 180 to allow the transistor 180 to tie the input of the spare cell 124 to VSS (i.e., a low rail), as discussed further below. For example, the circuit 182 may turn on the transistor 180 by tying the gate of the transistor 180 to VDD. This assumes that VDD exceeds the threshold voltage of the transistor 180. When the transistor 180 is turned on by the circuit 182, the transistor 180 couples the input of the spare cell 124 to VSS (i.e., a low rail) through the channel of the transistor 180.

The chip also includes a low rail 310 that extends in lateral direction 114. The low rail 310 may be formed from the same metal layer (e.g., metal layer M0) as the first metal routing 312 and the second metal routing 314 (e.g., using photolithography and etching). The low rail 310 is at the voltage VSS (e.g., ground). In the example in FIG. 3A, the low rail 310 is coupled to the vias 216 and 218 in the tie cell 120, which couple the low rail 310 to the source of the transistor 180. Thus, in this example, the drain of the transistor 180 is coupled to the input of the spare cell 124 through the first metal routing 312, and the source of the transistor 180 is coupled to the low rail 310. Therefore, when the transistor 180 is turned on by the circuit 182, the transistor 180 couples the input of the spare cell 124 to VSS by coupling the input of the spare cell 124 to the low rail 310. For the example where the spare cell 124 provides an inverter, the input of the spare cell 124 corresponds to the input of the inverter (e.g., the gates of the first transistor 126 and the second transistor 128).

The low rail 310 may also be coupled to the vias 236 and 238 in the spare cell 124 to couple the source of the second transistor 128 (e.g., NFET) to VSS, as shown in the example in FIG. 3A. It is to be appreciated that, in some implementations, separate low rails may be used for the spare cell 124 and the tie cell 120 (e.g., by cutting the low rail 310 shown in FIG. 3A into separate low rails for the tie cell 120 and the spare cell 124).

The chip also includes a supply rail 318 that extends in lateral direction 114. The supply rail 318 may be formed from the same metal layer (e.g., metal layer M0) as the first metal routing 312 and the second metal routing 314 (e.g., using photolithography and etching). The supply rail 318 provides supply voltage VDD (e.g., from a power distribution network). In the example in FIG. 3A, the supply rail 318 is coupled to the vias 240 and 244 in the spare cell 124, which couple the supply rail 318 to the source of the first transistor 126 (e.g., PFET).

The chip also includes a third metal routing 316 that extends in lateral direction 114. The third metal routing 316 is coupled to the via 242 in the spare cell 124. In this example, the via 242 couples the third metal routing 316 to the drain of the first transistor 126 and the drain of the second transistor 128, which provide the output of the spare cell 124 (e.g., output of the inverter in the spare cell 124) in this example. The third metal routing 316 may be used to couple the output of the spare cell 124 to one or more other cells (not shown) when the spare cell 124 is active.

FIG. 3B shows an example of a layout of the metal routing for the case in which the spare cell 124 is active. In this case, the first metal routing 312 is cut into a first portion 312-1 and a second portion 312-2 to decouple the input of the spare cell 124 from the tie cell 120. For example, the first metal routing 312 may be cut 320 in the MTO layer (e.g., using a photolithographic process and an etching process in which the cut 320 is defined by a cut pattern (also referred to as a cut layer) in a mask). In this case, the first portion 312-1 may be coupled to one or more other cells (not shown) to couple the input of the spare cell 124 to the one or more other cells. Also, the third metal routing 316 may be coupled to one or more other cells (not shown) to couple the output of the spare cell 124 to the one or more other cells.

Thus, in this example, the spare cell 124 may be made active (e.g., to implement a circuit design change) by cutting the first metal routing 312 in the MTO layer. This allows an ECO to implement a circuit design change in the MTO layer using the spare cell 124 without having to change the BTO layer.

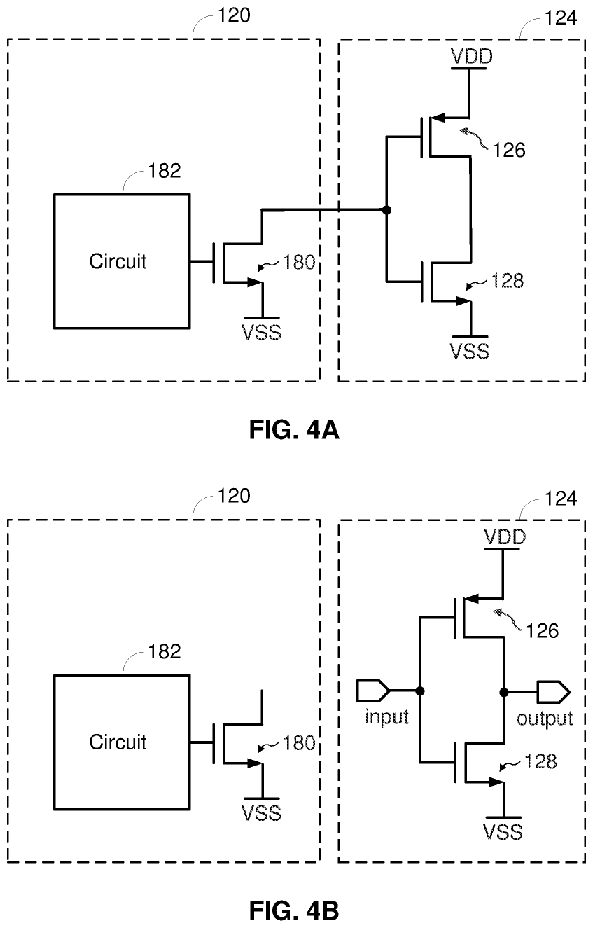

FIG. 4A shows a circuit diagram of the spare cell 124 and the tie cell 120 for the case where the spare cell 124 is inactive according to certain aspects of the present disclosure. In this example, the first transistor 126 (e.g., PFET) and the second transistor 128 (e.g., NFET) implement an inverter (e.g., complementary inverter). The source of the first transistor 126 (e.g., PFET) is coupled to VDD and the source of the second transistor 128 is coupled to VSS. Also, the gates of the transistors 126 and 128 (i.e., the gates 136 and 138 in FIGS. 1, 2, and 3A) are coupled to the input of the spare cell 124, and the drains of the transistors 126 and 128 are coupled to the output of the spare cell 124. In this example, the drain of the transistor 180 in the tie cell 120 is coupled to the input of the spare cell 124 through the first metal routing 312 shown in FIG. 3A, and the source of the transistor 180 in the tie cell 120 is coupled to VSS.

Also, in this example, the circuit 182 is coupled to the gate of the transistor 180 in the tie cell 120 via the interconnect 330 shown in FIG. 3A. The circuit 182 is configured to turn on the transistor 180 in the tie cell 120. This causes the transistor 180 to couple the input of the spare cell 124 to VSS (i.e., tie the input of the spare cell 124 to VSS).

FIG. 4B shows a circuit diagram of the spare cell 124 and the tie cell 120 for the case wherein the spare cell 124 is active according to certain aspects of the present disclosure. In this example, the input of the spare cell 124 is decoupled from the drain of the transistor 180 in the tie cell 120 (e.g., by cutting the first metal routing 312 as shown in FIG. 3B). In this case, the input of the spare cell 124 may be coupled to one or more other cells (not shown), and the output of the spare cell 124 may be coupled to one or more other cells (not shown) (e.g., to implement a circuit design change).

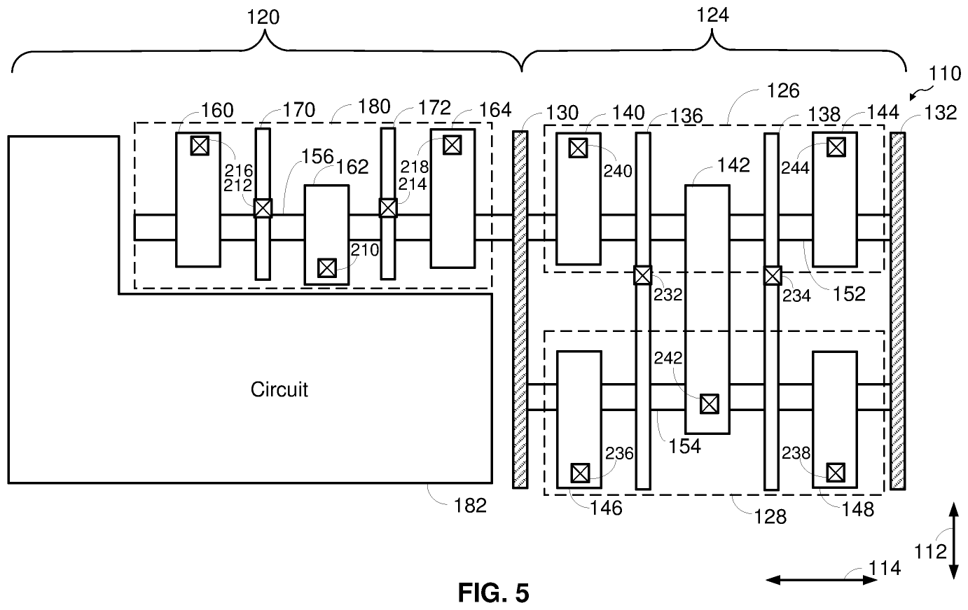

In some implementations, the transistor 180 may be implemented with a PFET. In this regard, FIG. 5 shows an example in which the transistor 180 is a PFET according to certain aspects. In this example, the active region 156 may be a p-type active region (e.g., OD) that is formed using p+ diffusion, p+ implantation, or another process. In certain aspect, the active region 156 in the tie cell 120 and the first active region 152 in the spare cell 124 may be formed from a longer active region that is cut under the first dummy gate 130 to form the active regions 152 and 156.

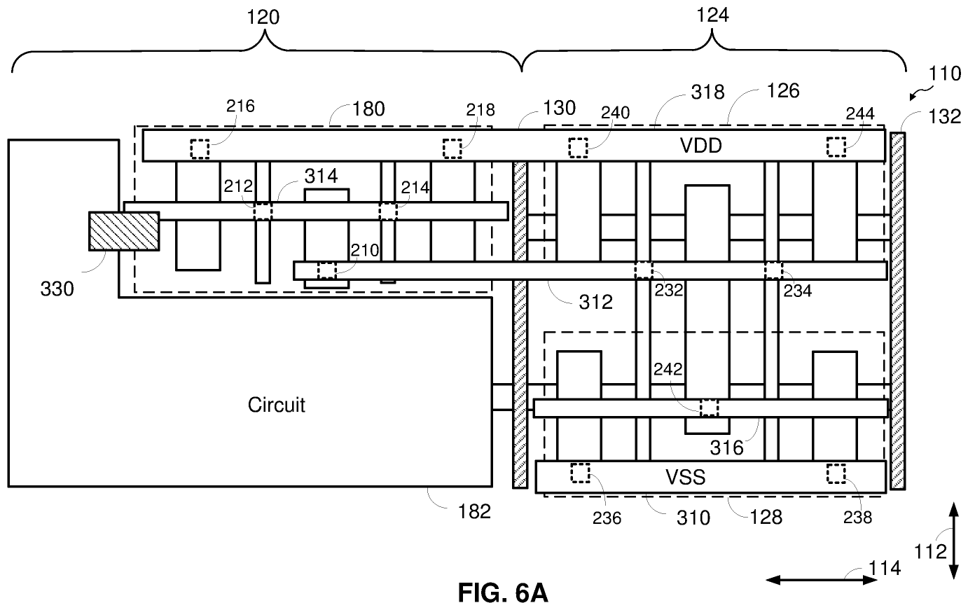

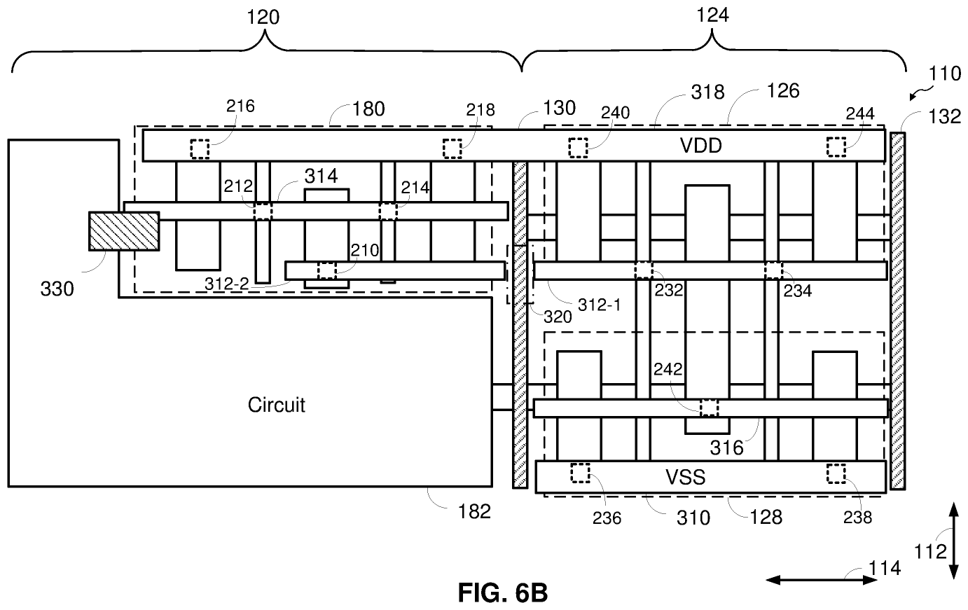

As discussed above, the via 210 on the second source/drain contact 162 is aligned with the gate vias 232 and 234 in the spare cell 124 in the lateral direction 112. This allows the drain of the transistor 180 to be coupled with the input of the spare cell 124 by the first metal routing 312 (shown in FIG. 6A).

FIG. 6A shows an example of a layout of metal routing over the spare cell 124 and the tie cell 120 for the case where the spare cell 124 is inactive. As shown in FIG. 6A, the first metal routing 312 extends in lateral direction 114, and is coupled to the via 210 in the tie cell 120 and the gate vias 232 and 234 in the spare cell 124. In this case, the first metal routing 312 couples the input of the spare cell 124 to the transistor 180 in the tie cell 120. More particularly, in the example in FIG. 6A, the first metal routing 312 couples the gates 136 and 138 of the first and second transistors 126 and 128 in the spare cell 124 to the drain of the transistor 180 in the tie cell 120. As discussed further below, in this example, the transistor 180 ties the input of the spare cell 124 to VDD, which helps prevent current from flowing through the spare cell 124 and therefore reduce leakage current.

In the example in FIG. 6A, the supply rail 318 is coupled to the vias 216 and 218 in the tie cell 120. As a result, the source of the transistor 180 (e.g., PFET) is coupled to VDD in this example. It is to be appreciated that, in some implementations, separate supply rails may be used for the spare cell 124 and the tie cell 120 (e.g., by cutting the supply rail 318 shown in FIG. 6A into separate supply rails).

As discussed above, the circuit 182 is configured to turn on the transistor 180. In this example, turning on the transistor 180 causes the transistor 180 to couple the input of the spare cell 124 to the supply rail 318 (and hence VDD) through the channel of the transistor 180. Thus, in this example, the tie cell 120 ties the input of the spare cell 124 to VDD. In this example, the circuit 182 may turn on the transistor 180 by tying the gate of the transistor 180 to VSS (i.e., low rail) since the transistor 180 is implemented with the PFET is this example.

FIG. 6B shows an example of a layout of the metal routing for the case in which the spare cell 124 is active. In this case, the first metal routing 312 is cut into the first portion 312-1 and the second portion 312-2 to decouple the input of the spare cell 124 from the tie cell 120. For example, the first metal routing 312 may be cut 320 in the MTO layer. Thus, in this example, the spare cell 124 may be made active (e.g., to implement a circuit design change) by cutting the first metal routing 312 in the MTO layer.

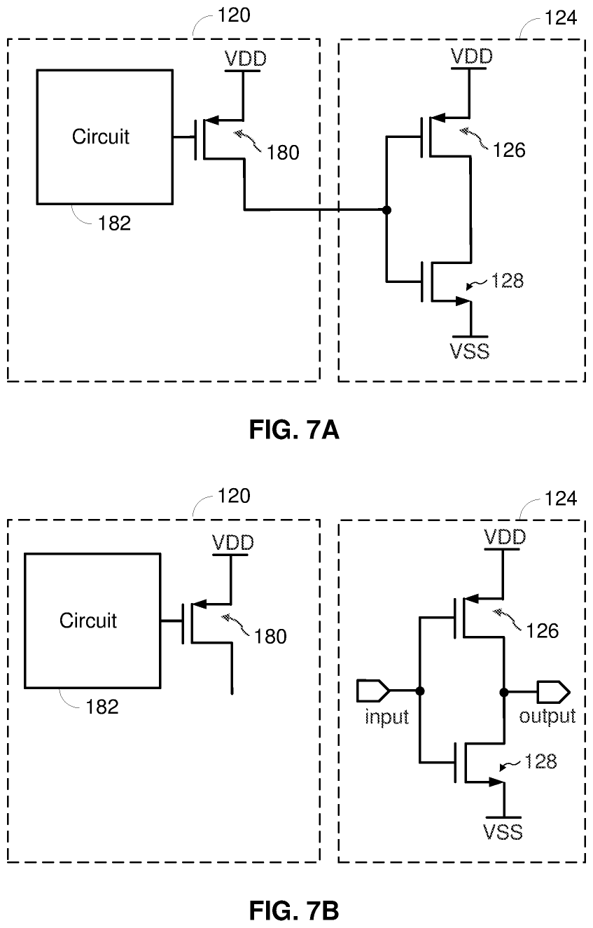

FIG. 7A shows a circuit diagram of the spare cell 124 and the tie cell 120 for the case where the spare cell 124 is inactive according to certain aspects of the present disclosure. In this example, the drain of the transistor 180 in the tie cell 120 is coupled to the input of the spare cell 124 through the first metal routing 312 shown in FIG. 6A, and the source of the transistor 180 in the tie cell 120 is coupled to VDD. Also, in this example, the circuit 182 is configured to turn on the transistor 180 in the tie cell 120. This causes the transistor 180 to couple the input of the spare cell 124 to VDD.

FIG. 7B shows a circuit diagram of the spare cell 124 and the tie cell 120 for the case wherein the spare cell 124 is active according to certain aspects of the present disclosure. In this example, the input of the spare cell 124 is decoupled from the drain of the transistor 180 in the tie cell 120 (e.g., by cutting the first metal routing 312 as shown in FIG. 6B). In this case, the input of the spare cell 124 may be coupled to one or more other cells (not shown), and the output of the spare cell 124 may be coupled to one or more other cells (not shown) (e.g., to implement a circuit design change).

Thus, the transistor 180 in the tie cell 120 may be implemented with an NFET (shown in FIGS. 1, 2, 3A and 3B) or a PFET (shown in FIGS. 5, 6A and 6B). In both cases, the drain of the transistor 180 is coupled to the input of the spare cell 124 through the first metal routing 312 when the spare cell 124 is inactive. For the NFET implementation, the source of the transistor 180 is coupled to a low rail (e.g., the low rail 310), which is at the voltage VSS. For the PFET implementation, the source of the transistor 180 is coupled to a supply rail (e.g., the supply rail 318), which is at the supply voltage VDD. Thus, the tie cell 120 ties the input of the spare cell 124 high (i.e., VDD) or low (i.e., VSS) depending on whether the transistor 180 is implemented with the NFET or the PFET.

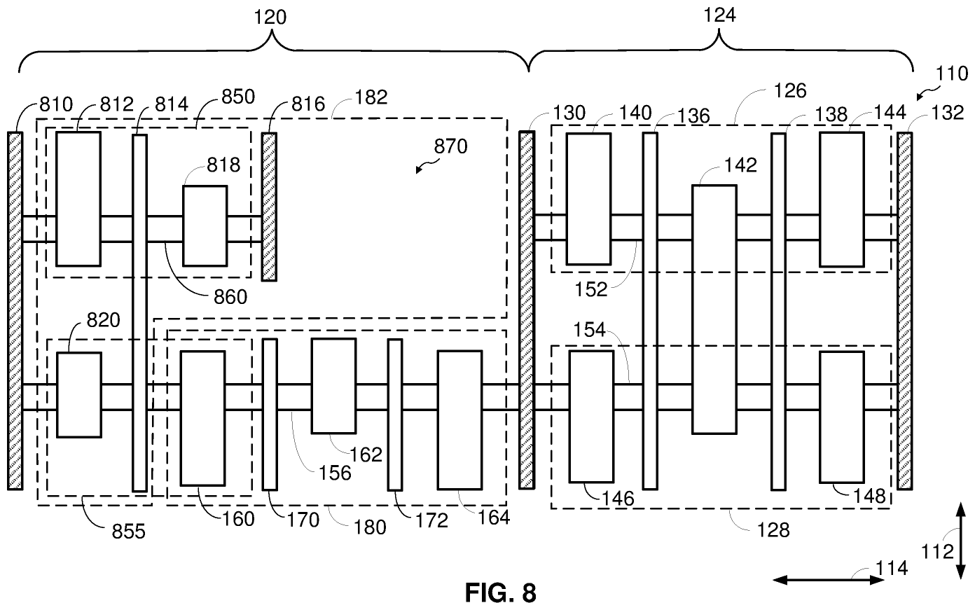

FIG. 8 shows an exemplary implementation of the circuit 182 according to certain aspects. In this example, the chip includes a third dummy gate 810 and a fourth dummy gate 816. The third dummy gate 810 and the fourth dummy gate 816 may each be implemented with a PODE. However, it is to be understood that the third dummy gate 810 and the fourth dummy gate 816 are not limited to this example. In the example shown in FIG. 8, each of the dummy gates 810 and 816 is elongated and extends in lateral direction 112.

In this example, the circuit 182 includes a first transistor 850 and a second transistor 855. The first transistor 850 may be a PFET and the second transistor 855 may be an NFET. However, it is to be appreciated that the present disclosure in not limited to this example. FIG. 8 shows an exemplary layout for the first transistor 850 and the second transistor 855, which is discussed further below.

In the example in FIG. 8, the tie cell 120 includes an active region 860 extending in lateral direction 114 between the third dummy gate 810 and the fourth dummy gate 816. In this example, the active region 860 may be a p-type active region (e.g., OD) that is formed using p+ diffusion, p+ implantation, or another process.

In the example in FIG. 8, the tie cell 120 has additional space 870 between the fourth dummy gate 816 and the first dummy gate 130 (e.g., due to the layout of the circuit 182). The space 870 may include one or more structures (not shown) such as one or more gates (e.g., for pattern matching), one or more source/drain contacts, etc. It is to be appreciated that, in some implementations, the tie cell 120 may not have the additional space 870.

In the example in FIG. 8, the tie cell 120 includes a third gate 814 extending in lateral direction 112 over the active region 860 and the active region 156. The portion of the active region 860 under the third gate 814 forms the channel of the first transistor 850 and the portion of the active region 156 under the third gate 814 forms the channel of the second transistor 855. In this example, the third gate 814 provides the gate of the first transistor 850 and the gate of the second transistor 855.

In the example in FIG. 8, the tie cell 120 further includes a fourth source/drain contact 812, a fifth source/drain contact 818, and a sixth source/drain contact 820. The fourth source/drain contact 812 is disposed over a portion of the active region 860 between the third dummy gate 810 and the third gate 814, and the fifth source/drain contact 818 is disposed over a portion of the active region 860 between the third gate 814 and the fourth dummy gate 816. In this example, the fourth source/drain contact 812 may provide a source contact for the first transistor 850, and the fifth source/drain contact 818 may provide a drain contact for the first transistor 850.

The sixth source/drain contact 820 is disposed over a portion of the active region 156 between the third dummy gate 810 and the third gate 814. In this example, the sixth source/drain contact 820 may provide a drain contact for the second transistor 855. Also, the first source/drain contact 160 may provide a source contact for the second transistor 855. Thus, in this example, the first source/drain contact 160 may be shared by the second transistor 855 and the transistor 180. However, it is to be appreciated that the present disclosure is not limited to this example.

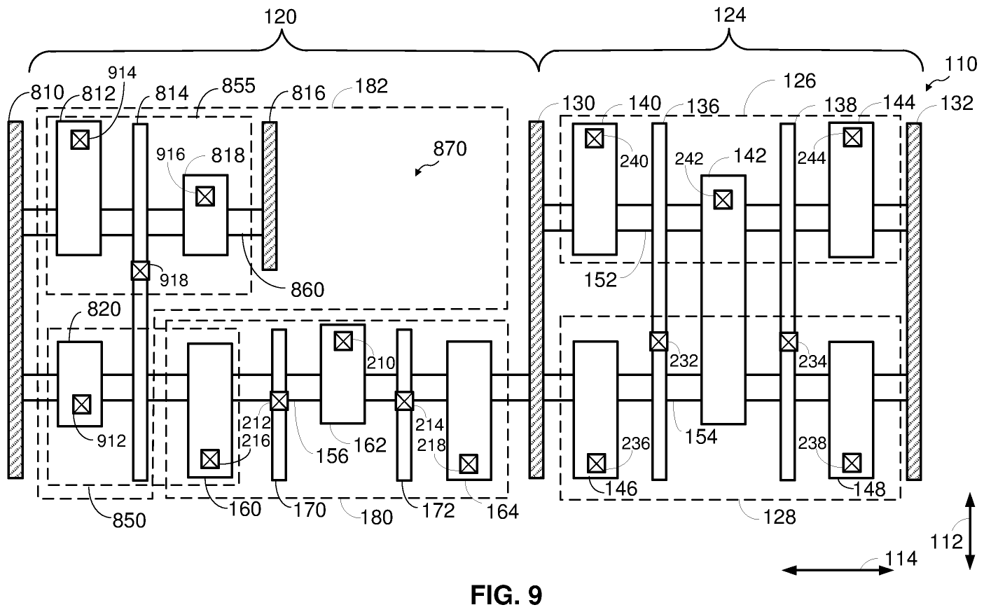

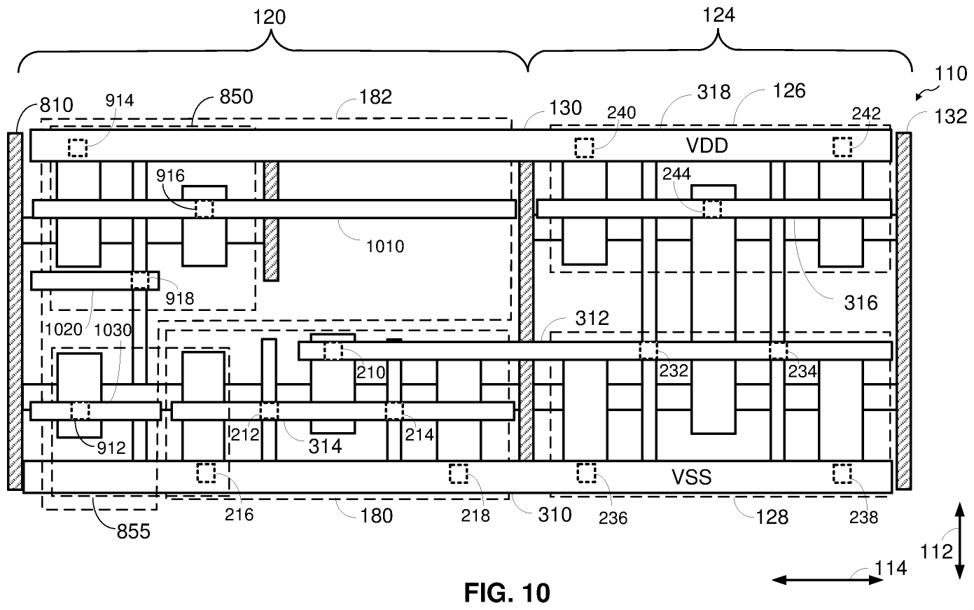

FIG. 9 shows an example of vias used to couple various structures of the circuit 182 to metal routing (shown in FIGS. 10, 11, 12A, and 12B). In this example, the chip includes a gate via 918 disposed on the third gate 814. It is to be appreciated that, in some implementations, a gate contact (not shown in FIG. 9) may be disposed between the third gate 814 and the gate via 918. The chip may also include a via 914 disposed on the fourth source/drain contact 812, a via 916 disposed on the fifth source/drain contact 818, and a via 912 disposed on the sixth source/drain contact 820.

FIG. 10 shows an example of the layout of metal routing over the circuit 182. The metal routing shown in FIG. 10 may be formed from metal layer M0 in the MTO layer (e.g., using photolithography and etching), but is not limited to this example. For ease of illustration, the reference numbers of some of the structures in the tie cell 120 and the spare cell 124 are omitted in FIG. 10.

In this example, the chip includes a fourth metal routing 1010, a fifth metal routing 1020, and a sixth metal routing 1030. Each of the fourth metal routing 1010, the fifth metal routing 1020, and the sixth metal routing 1030 extends in lateral direction 114. The fourth metal routing 1010 is coupled to the fifth source/drain contact 818 through the via 916, the fifth metal routing 1020 is coupled to the third gate 814 through the gate via 918, and the sixth metal routing 1030 is coupled to the sixth source/drain contact 820 through the vias 912. Note that the vias 912, 916, and 918 are shown with dotted lines to indicate they are below the metal routing.

Also, in this example, the fourth source/drain contact 812 is coupled to the supply rail 318 by the via 914. Thus, in this example, the source of the first transistor 850 is coupled VDD. It is to be appreciated that, in some implementations, separate supply rails may be used for the spare cell 124 and the tie cell 120 (e.g., by cutting the supply rail 318 shown in FIG. 10).

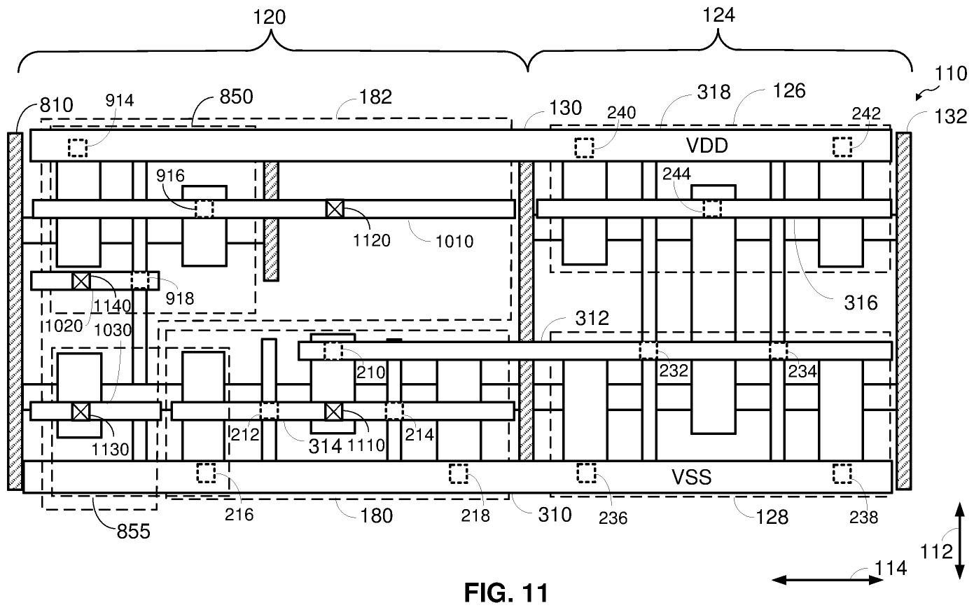

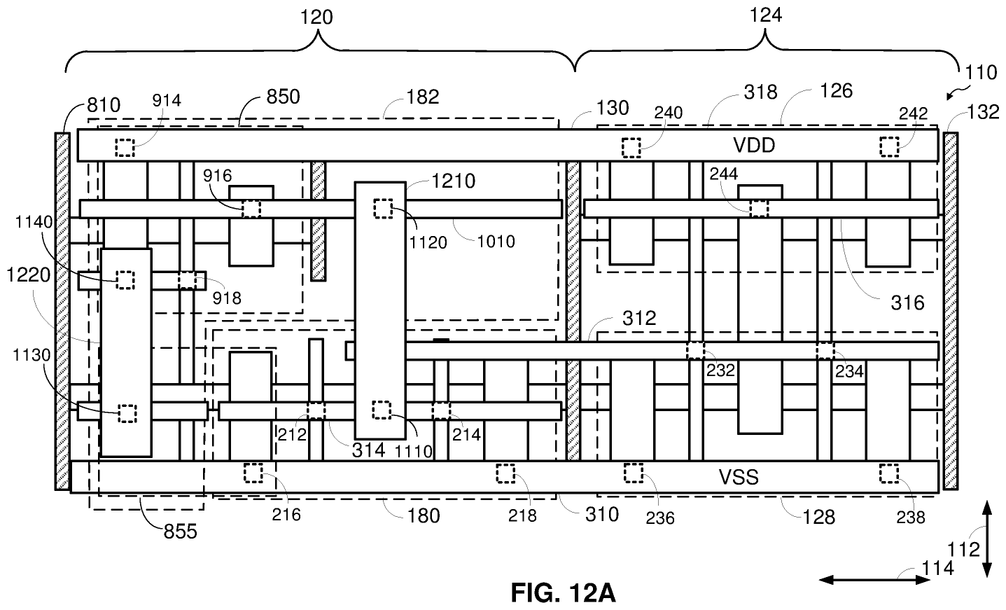

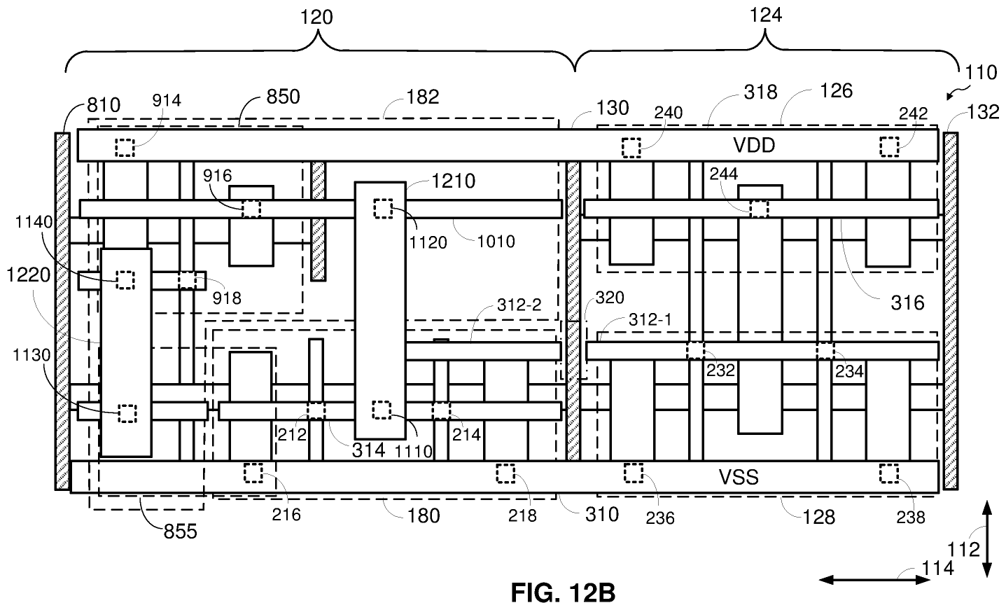

FIG. 11 shows an example of vias disposed on the metal routing shown in FIG. 10 to provide coupling to a higher metal layer (e.g., metal layer M1) shown in FIGS. 12A and 12B. The vias include a via 1110 disposed on the second metal routing 314, a via 1120 disposed on the fourth metal routing 1010, a vias 1140 disposed on the fifth metal routing 1020, and a via 1130 disposed on the sixth metal routing 1030. The vias 1110 and 1120 are aligned in the lateral direction 114, and the vias 1130 and 1140 are aligned in lateral direction 114.

FIG. 12A shows an example of a seventh metal routing 1210 and an eighth metal routing 1220 that are formed form a metal layer (e.g., metal layer M1) that is above the metal layer used to form the metal routing in FIG. 10. The seventh metal routing 1210 and the eighth metal routing 1220 each extends in lateral direction 112. The seventh metal routing 1210 is coupled to the second metal routing 314 through via 1110, and coupled to the fourth metal routing 1010 through via 1120. In this example, the via 1110, the seventh metal routing 1210, the via 1120, and the fourth metal routing 1010 provide the interconnect 330 shown in FIGS. 3A and 3B, and couple the gate of the transistor 180 to the drain of the first transistor 850 in the circuit 182.

The eighth metal routing 1220 is coupled to the fifth metal routing 1020 through via 1140, and coupled to the sixth metal routing 1030 through via 1130. In this example, the fifth metal routing 1020, the via 1140, the eighth metal routing 1220, and the via 1130 couple the drain of the second transistor 855 to the gate of the second transistor 855. Note that the gate of the first transistor 850 is coupled to the gate of the second transistor 855 since the first transistor 850 and the second transistor 855 share the third gate 814.

FIG. 12A shows the layout of the metal routing for the case where the spare cell 124 is inactive. In this case, the first metal routing 312 couples the input of the spare cell 124 to the tie cell 120, as discussed above.

FIG. 12B shows the layout of the metal routing for the case where the spare cell 124 is active. In this case, the first metal routing 312 is cut 320 into the first portion 312-1 and the second portion 312-2 to decouple the input of the spare cell 124 from the tie cell 120, as discussed above.

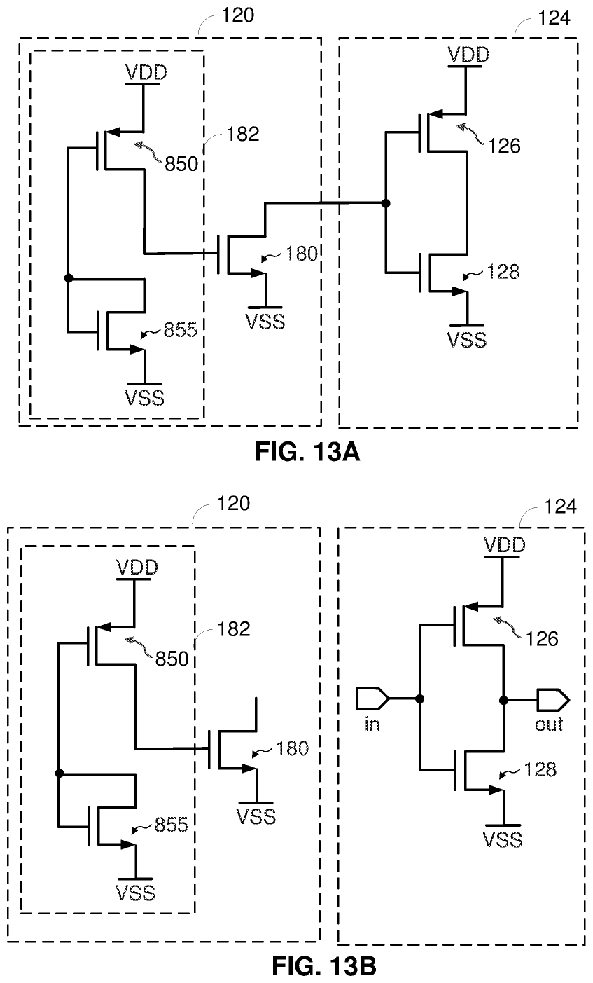

FIG. 13A shows a circuit diagram of the spare cell 124 and the tie cell 120 for the case where the spare cell 124 is inactive according to certain aspects of the present disclosure. In this example, the drain of the transistor 180 in the tie cell 120 is coupled to the input of the spare cell 124 through the first metal routing 312 shown in FIG. 12A, and the source of the transistor 180 in the tie cell 120 is coupled to VSS. Also, in this example, the source of the first transistor 850 in the circuit 182 is coupled to VDD, and the drain of the first transistor 850 in the circuit 182 is coupled to the gate of the transistor 180. The gate of the first transistor 850 in the circuit 182 is coupled to the gate and the drain of the second transistor 855 in the circuit 182. The source of the second transistor 855 in the circuit 182 is coupled to VSS. In this example, the first transistor 850 turns on and couples the gate of the transistor 180 to VDD through the channel of the first transistor 850 (i.e., ties the gate of the transistor to VDD). Coupling the gate of the transistor 180 to VDD causes the transistor 180 to turn on and couple the input of the spare cell 124 to VSS. In the example shown in FIG. 13A, the input of the spare cell 124 correspond to the input of the inverter formed by the first transistor 126 and the second transistor 128 in the spare cell 124. However, it is to be appreciated that the present disclosure is not limited to this example.

FIG. 13B shows a circuit diagram of the spare cell 124 and the tie cell 120 for the case wherein the spare cell 124 is active according to certain aspects of the present disclosure. In this example, the input of the spare cell 124 is decoupled from the drain of the transistor 180 in the tie cell 120 (e.g., by cutting the first metal routing 312 as shown in FIG. 12B). In this case, the input of the spare cell 124 may be coupled to one or more other cells (not shown), and the output of the spare cell 124 may be coupled to one or more other cells (not shown) (e.g., to implement a circuit design change).

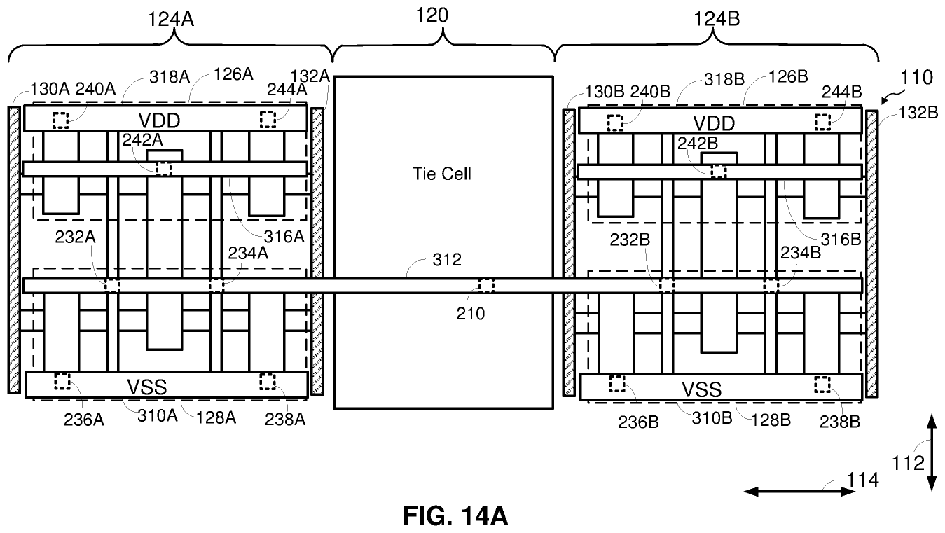

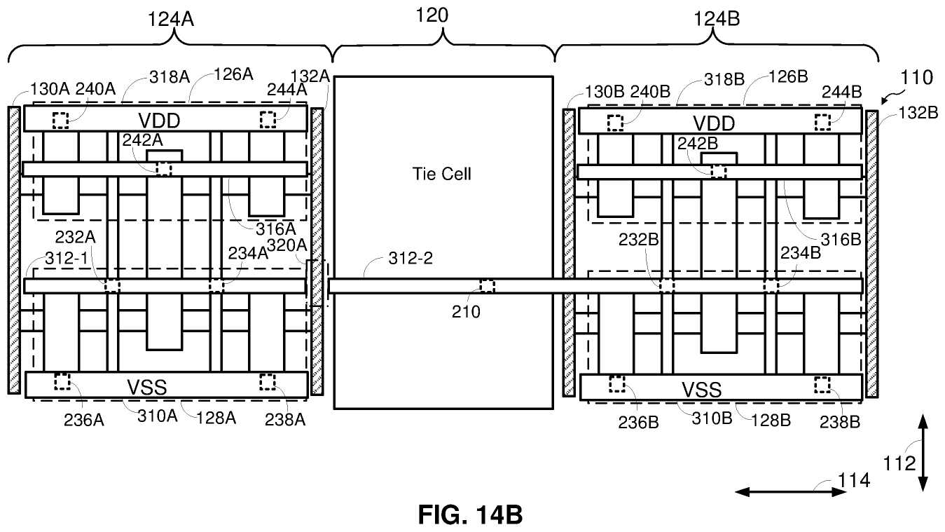

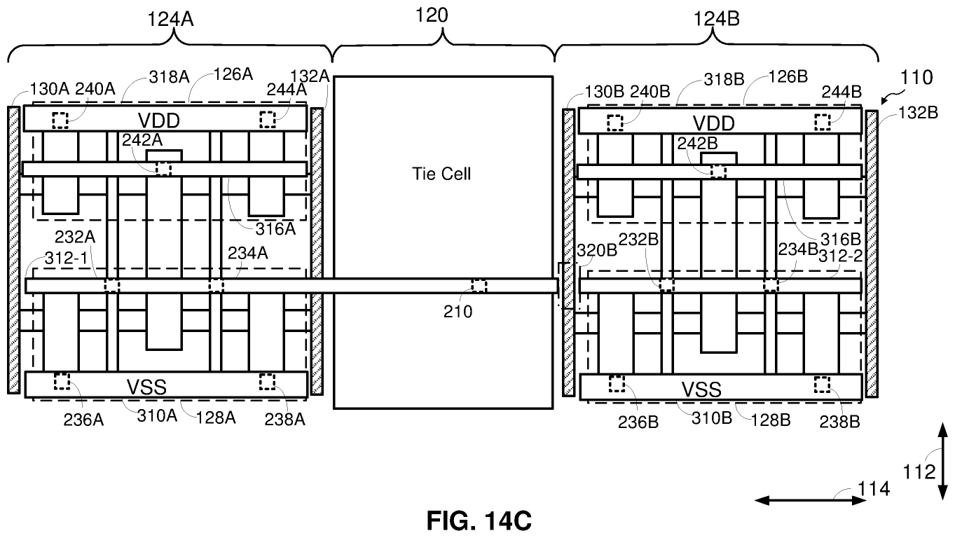

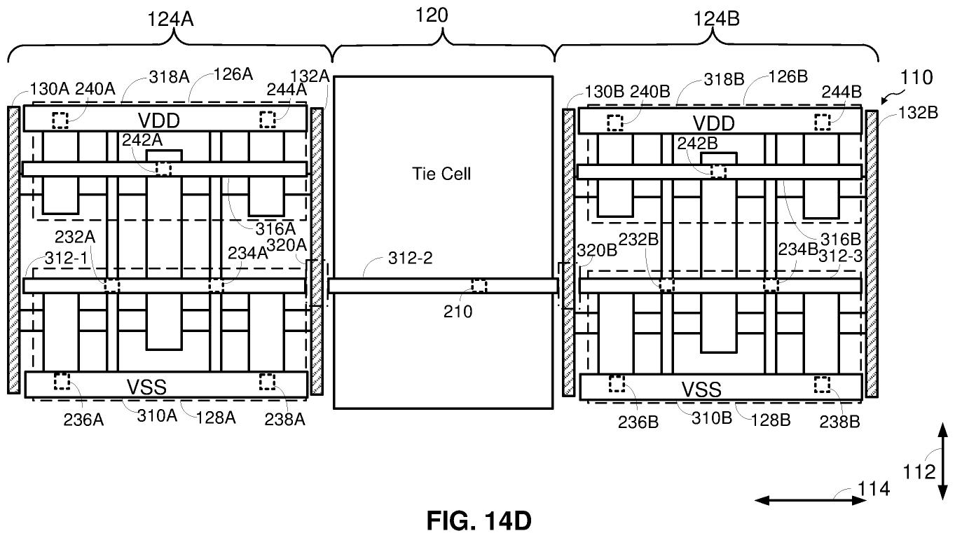

It is to be appreciated that the tie cell 120 is not limited to a single spare cell, and may be used with two or more spare cells. In this regard, FIG. 14A shows an example in which the tie cell 120 is used with a first spare cell 124A and a second spare cell 124B according to certain aspects. Each of the first spare cell 124A and the second spare cell 124B may be a separate instance (i.e., copy) of the spare cell 124 illustrated in any one or more of FIGS. 1, 2, 3A, 3B, 5, 6A, 6B, 8, 9, 10, 11, 12A, and 12B. In FIG. 14A, the reference numbers for the structures in the first spare cell 124A are appended with “A” and the reference numbers for the structures in the second spare cell 124B are appended with “B.” For ease of illustration, details of the tie cell 120 are not shown in FIG. 14A. The tie cell 120 may be implemented with any of one of the exemplary implementations shown in FIGS. 1, 2, 3A, 3B, 5, 6A, 6B, 8, 9, 10, 11, 12A, and 12B. Note that the tie cell 120 and the spare cells 124A and 124B are not necessarily drawn to scale in FIG. 14A.

In the example in FIG. 14A, the first spare cell 124A and the second spare cell 124B are located on opposite sides of the tie cell 120. However, it is to be appreciated that the present disclosure is not limited to this example.

FIG. 14A shows an example in which the first spare cell 124A and the second spare cell 124B are both inactive. In this example, the first metal routing 312 extends in lateral direction 114 across the first spare cell 124A, the tie cell 120, and the second spare cell 124B. In this example, the first metal routing 312 crosses over the dummy gate 132A between the first spare cell 124A and the tie cell 120, and crosses over the dummy gate 130B between the tie cell 120 and the second spare cell 124B. As discussed above, the first metal routing 312 may be formed from a metal layer (e.g., metal layer M0) in the MTO (e.g., using photolithography and etching). In certain aspects, the first metal routing 312 is a metal line patterned from the metal layer in the MTO layer.

The first metal routing 312 is coupled to the drain of the transistor 180 in the tie cell 120 (shown in FIGS. FIGS. 1, 2, 3A, 3B, 5, 6A, 6B, 8, 9, 10, 11, 12A, and 12B) through via 210. The first metal routing 312 is also coupled to the input of the first spare cell 124A through vias 232A and 234A. In this example, the vias 232A and 234 couple the first metal routing 312 to the gates of the first transistor 126A and the second transistor 128A in the first spare cell 124A. The first metal routing 312 is also coupled to the input of the second spare cell 124B through vias 232B and 234B. In this example, the vias 232B and 234B couple the first metal routing 312 to the gates of the first transistor 126B and the second transistor 128B in the second spare cell 124B.

In this example, the transistor 180 in the tie cell 120 couples the input of the first spare cell 124A and the input of the second spare cell 124B to VSS (i.e., a low rail) or VDD (i.e., a supply rail) through the channel of the transistor 180. This reduces current leakage in the spare cells 124A and 124B when the spare cells 124A and 124B are inactive, as discussed above.

FIG. 14B shows an example in which the first spare cell 124A is active and the second spare cell 124B is inactive. In this case, the first metal routing 312 is cut 320A between the first spare cell 124A and the tie cell 120 into a first portion 312-1 and a second portion 312-2 to decouple the input of the first spare cell 124A from the tie cell 120. The first metal routing 312 is cut in the MTO layer (e.g., using a photolithographic process and an etching process). In this example, the input of the second spare cell 124B remains coupled to the tie cell 120 through the second portion 312-2. Thus, the first spare cell 124A may be made active (e.g., to implement a circuit design change) by cutting the first metal routing 312 between the first spare cell 124A and the tie cell 120 while leaving the second spare cell 124B inactive.

FIG. 14C shows an example in which the first spare cell 124A is inactive and the second spare cell 124B is active. In this case, the first metal routing 312 is cut 320B between the second spare cell 124B and the tie cell 120 into a first portion 312-1 and a second portion 312-2 to decouple the input of the second spare cell 124B from the tie cell 120. The first metal routing 312 is cut in the MTO layer (e.g., using a photolithographic process and an etching process). In this example, the input of the first spare cell 124A remains coupled to the tie cell 120 through the first portion 312-1. Thus, the second spare cell 124B may be made active (e.g., to implement a circuit design change) by cutting the first metal routing 312 between the second spare cell 124B and the tie cell 120 while leaving the first spare cell 124A inactive.

FIG. 14D shows an example in which the first spare cell 124A and the second spare cell 124B are both active. In this case, the first metal routing 312 is cut 320A between the first spare cell 124A and the tie cell 120 to decouple the first spare cell 124A from the tie cell 120. The first metal routing 312 is also cut 320B between the second spare cell 124B and the tie cell 120 to decouple the second spare cell 124B from the tie cell 120. As shown in FIG. 14D, the first metal routing 312 is cut into a first portion 312-1, a second portion 312-2, and a third portion 312-3. The first metal routing 312 is cut in the MTO layer (e.g., using a photolithographic process and an etching process).

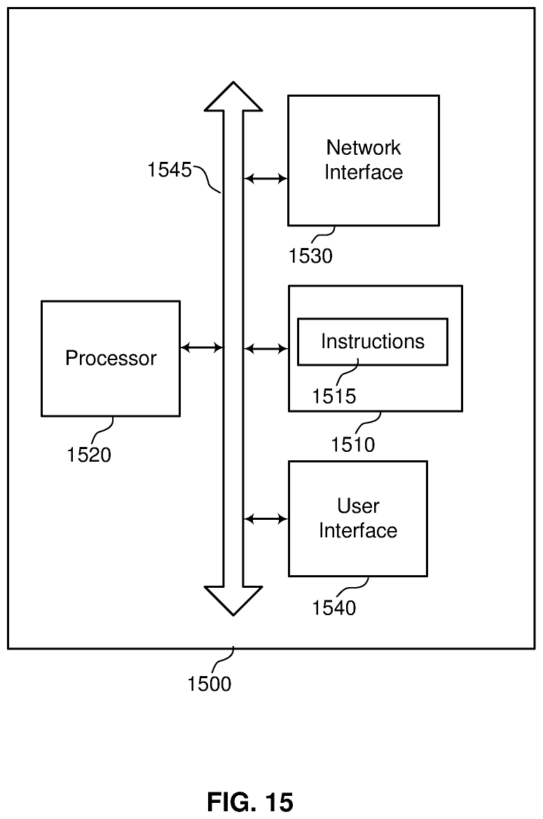

In certain aspects, the exemplary layouts discussed above may be determined using a computer system. In this regard, FIG. 15 illustrates a computer system 1500 that may be used to determine layouts for the BTO layer and/or the MTO layer of the chip according to certain aspects. The computer system 1500 may include a processor 1520, a memory 1510, a network interface 1530, and a user interface 1540. These components may be in electronic communication via one or more buses 1545.

The memory 1510 may store instructions 1515 that are executable by the processor 1520 to cause the computer system 1500 to perform one or more of the operations described herein. The processor 1520 may include a general-purpose processor, a digital signal processor (DSP), a central processing unit (CPU), a microcontroller, an application specific integrated circuit (ASIC), a field programmable gate array (FPGA), a programmable logic device, a discrete gate or transistor logic component, a discrete hardware component, or any combination thereof. The memory 1510 may include, by way of example, random access memory (RAM), flash memory, read only memory (ROM), programmable read only memory (PROM), erasable programmable read only memory (EPROM), electrically erasable programmable read only memory (EEPROM), registers, magnetic disks, optical disks, hard drives, or any other suitable storage medium, or any combination thereof. The memory 1510 may also store one or more files specifying layouts for various layers of a chip. For example, the one or more files may specify the layout of metal routing (e.g., first metal routing 312) formed from metal layer M0, metal layer M1, etc.

The network interface 1530 is configured to interface the computer system 1500 with one or more other devices. For example, the network interface 1530 may receive a file specifying an initial layout for metal routing on a chip, a file specifying the layout of spare cells and tie cells (e.g., tie cell 120, spare cell 124, first spare cell 124A, second spare cell 124B, etc.) on the chip, and a file indicting a change in a circuit design on the chip. In this example, the processor 1520 may determine a spare cell for implementing the change in circuit design, and change (i.e., modify) the layout of the metal routing to active the spare cell. The processor 1520 may also change the layout of the metal routing to couple the activated spare cell with one or more other cells on the chip. After changing the layout of the metal routing, the processor 1520 may generate and store a file specifying the layout of the metal routing with the changes in the memory 1510. The file may then be used to generate one or more masks for implementing the layout on the chip during fabrication (e.g., using photolithography).

The user interface 1540 may be configured to receive data from a user (e.g., via keypad, mouse, etc.) and provide the data to the processor 1520. The user interface 1540 may also be configured to output data from the processor 1520 to the user (e.g., via a display, a speaker, etc.).

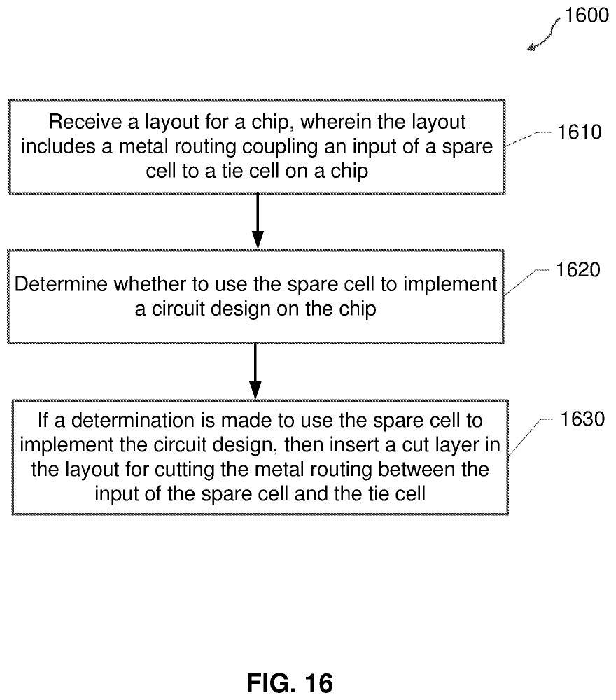

FIG. 16 illustrates a method 1600 for chip layout according to certain aspects of the present disclosure. The method 1600 maybe performed by the computer system 1500 according to certain aspects.

At block 1610, a layout for a chip is received, wherein the layout includes a metal routing coupling an input of a spare cell to a tie cell on a chip. For example, the processor 1520 may receive the layout in a file from the memory 1510 and/or the network interface 1530. The metal routing may correspond to the first metal routing 312, the spare cell may correspond to the spare cell 124, and the tie cell may correspond to the tie cell 120.

At block 1620, a determination is made whether to use the spare cell to implement a circuit design on the chip. For example, the determination may be made based on whether a logic gate in the spare cell (e.g., inverter) is included in the circuit design. If the circuit design includes the logic gate, then the processor 1520 may determine to use the spare cell to implement the logic gate in the circuit design. In certain aspects, the circuit design may include one or more changes from an earlier circuit design for the chip.

At block 1630, if a determination is made to use the spare cell to implement the circuit design, then a cut layer is inserted in the layout for cutting the metal routing between the input of the spare cell and the tie cell. For example, the processor 1520 may insert the cut layer in the layout and store the layout with the cut layer in a file. The processor 1520 may store the file in the memory 1510 and/or send the file to another computer system using the network interface 1530. In certain aspects, the cut layer may specify a cut pattern in a mask that defines which portions of the metal layer (e.g., metal layer M0) used to form the metal routing (e.g., first metal routing 312) are to be cut during fabrication. The cut layer may also be referred to as cut metal, or another term.

The method 1600 may also include, if a determination is made not to use the spare cell to implement the circuit design, leaving the metal routing between the input of the spare cell and the tie cell unchanged. For example, the metal routing (e.g., metal routing 312) may be left uncut between the input of the spare cell and the tie cell. In this example, the tie cell may be configured to tie the input of the spare cell to VDD or VSS depending on the implementation of the tie cell.

It is to be appreciated that the present disclosure is not limited to the nomenclature in which the bottom-most metal layer in the MTO layer is designated metal layer M0. For instance, in another example, the bottom-most metal layer may be designated metal layer M1 instead of metal layer M0. It is also to be appreciated that a PFET may also be referred to as a p-type metal oxide semiconductor (PMOS) transistor, and an NFET may also be referred to as an n-type metal oxide semiconductor (NMOS) transistor. A chip may also be referred to as a die.

Implementation examples are described in the following numbered clauses:
1. A chip, comprising:
   a spare cell including:
      a first active region; and
      a first gate extending over the first active region in a first direction;
   a tie cell including:
      a second active region;
      a second gate extending over the second active region in the first direction;
      a first drain contact formed over the second active region;
      a first source contact formed over the second active region, wherein the second gate is between the first drain contact and the first source contact, and first source contact is coupled to a first rail; and
      a circuit configured to couple the second gate to a second rail; and
   a metal routing extending in a second direction, wherein the second direction is perpendicular to the first direction, and the first metal routing is coupled to the first drain contact and the first gate.
2. The chip of clause 1, wherein the first rail comprises a low rail, the second rail comprises a supply rail, and the low rail has a lower potential than the supply rail.
3. The chip of clause 1, wherein the first rail comprises a supply rail, the second rail comprises a low rail, and the low rail has a lower potential than the supply rail.
4. The chip of any one of clauses 1 to 3, wherein the metal routing is formed from a metal layer M0.
5. The chip of clause 4, wherein the metal routing comprises a metal line formed from the metal layer M0.
6. The chip of clause 4 or 5, further comprising:
   a first via disposed on the first gate; and
   a second via disposed on the first drain contact, wherein the metal routing extends over the first via and the second via.
7. The chip of clause 6, wherein the first via and the second via are aligned in the first direction.
8. The chip of any one of clauses 1 to 7, further comprising a dummy gate between the spare cell and the tie cell, wherein the dummy gate extends in the first direction, and the metal routing crosses over the dummy gate.
9. The chip of clause 8, wherein the dummy gate comprises a poly over diffusion edge (PODE).
10. The chip of any one of clauses 1 to 9, wherein the spare cell further comprises:
   a third active region, wherein the first gate extends over the third active region;
   a second drain contact formed over the first active region and the third active region, wherein the second drain contact extends in the first direction.
11. The chip of clause 10, wherein the spare cell further comprises:
   a second source contact formed over the first active region, wherein the first gate is between the second source contact and the second drain contact, and the second source contact is coupled to the second rail; and
   a third source contact formed over the third active region, wherein the first gate is between the third source contact and the second drain contact, and the third source contact is coupled to the first rail.
12. The chip of clause 11, wherein the first active region is a p-type active region, and the third active region is an n-type active region.
13. The chip of clause 11 or 12, wherein the first rail comprises a low rail, the second rail comprises a supply rail, and the low rail has a lower potential than the supply rail.
14. A chip, comprising:
   a first spare cell including:
      a first active region; and
      a first gate extending over the first active region in a first direction;
   a second spare cell including:
      a second active region; and
      a second gate extending over the second active region in the first direction;
   a tie cell including:
      a third active region;
      a third gate extending over the third active region in the first direction;
      a first drain contact formed over the third active region;
      a first source contact formed over the third active region, wherein the third gate is between the first drain contact and the first source contact, and the first source contact is coupled to a first rail; and
      a circuit configured to couple the third gate to a second rail; and
      a metal routing extending in a second direction, wherein the second direction is perpendicular to the first direction, and the first metal routing is coupled to the first drain contact, the first gate, and the second gate.
15. The chip of clause 14, wherein the first rail comprises a low rail, the second rail comprises a supply rail, and the low rail has a lower potential than the supply rail.
16. The chip of clause 14, wherein the first rail comprises a supply rail, the second rail comprises a low rail, and the low rail has a lower potential than the supply rail.
17. The chip of any one of clauses 14 to 16, wherein the metal routing is formed from a metal layer M0.
18. The chip of clause 17, wherein the metal routing comprises a metal line formed from the metal layer M0.
19. The chip of clause 17 or 18, further comprising:
   a first via disposed on the first gate;
   a second via disposed on the second gate; and
   a third via disposed on the first drain contact, wherein the metal routing extends over the first via, the second via, and the third via.
20. The chip of clause 19, wherein the first via, the second via, and the third via are aligned in the first direction.
21. The chip of any one of clauses 14 to 20, further comprising:
   a first dummy gate between the tie cell and the first spare cell, wherein the first dummy gate extends in the first direction;
   a second dummy gate between the tie cell and the second spare cell, wherein the second dummy gate extends in the first direction, and the metal routing crosses over the first dummy gate and the second dummy gate.
22. The chip of clause 21, wherein the first dummy gate comprises a first poly over diffusion edge (PODE), and the second dummy gate comprises a second PODE.
23. The chip of clause 21 or 22, wherein the first spare cell and the second spare cell are located on opposite sides of the tie cell.
24. The chip of any one of clauses 14 to 23, wherein the first spare cell further comprises:
   a fourth active region, wherein the first gate extends over the fourth active region;
   a second drain contact formed over the first active region and the fourth active region, wherein the second drain contact extends in the first direction.
25. The chip of clause 24, wherein the first spare cell further comprises:
   a second source contact formed over the first active region, wherein the first gate is between the second source contact and the second drain contact, and the second source contact is coupled to the second rail; and
   a third source contact formed over the fourth active region, wherein the first gate is between the third source contact and the second drain contact, and the third source contact is coupled to the first rail.
26. The chip of clause 25, wherein the first active region is a p-type active region, and the fourth active region is an n-type active region.
27. The chip of clause 25 or 26, wherein the first rail comprises a low rail, the second rail comprises a supply rail, and the low rail has a lower potential than the supply rail.
28. A method for chip layout, comprising:
   receiving a layout for a chip, wherein the layout includes a metal routing coupling an input of a spare cell to a tie cell on the chip;
   determining whether to use the spare cell to implement a circuit design on a chip;
   if a determination is made to use the spare cell to implement the circuit design, then inserting a cut layer in the layout for cutting the metal routing between the input of the spare cell and the tie cell.
29. The method of clause 28, further comprising, if a determination is made not to use the spare cell to implement the circuit design, then leaving the metal routing between the input of the spare cell and the tie cell unchanged.
30. The method of clause 28 or 29, wherein the metal routing is formed from a metal layer M0.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a spare cell including:
a first active region; and
a first gate extending over the first active region in a first direction;
a tie cell including:
a second active region;
a second gate extending over the second active region in the first direction;
a first drain contact formed over the second active region;
a first source contact formed over the second active region, wherein the second gate is between the first drain contact and the first source contact, and first source contact is coupled to a first rail; and
a circuit configured to couple the second gate to a second rail; and
a metal routing extending in a second direction, wherein the second direction is perpendicular to the first direction, and the first metal routing is coupled to the first drain contact and the first gate.

2. The chip of claim 1, wherein the first rail comprises a low rail, the second rail comprises a supply rail, and the low rail has a lower potential than the supply rail.

3. The chip of claim 1, wherein the first rail comprises a supply rail, the second rail comprises a low rail, and the low rail has a lower potential than the supply rail.

4. The chip of claim 1, wherein the metal routing is formed from a metal layer M0.

5. The chip of claim 4, wherein the metal routing comprises a metal line formed from the metal layer M0.

6. The chip of claim 4, further comprising:
a first via disposed on the first gate; and
a second via disposed on the first drain contact, wherein the metal routing extends over the first via and the second via.

7. The chip of claim 6, wherein the first via and the second via are aligned in the first direction.

8. The chip of claim 1, further comprising a dummy gate between the spare cell and the tie cell, wherein the dummy gate extends in the first direction, and the metal routing crosses over the dummy gate.

9. The chip of claim 8, wherein the dummy gate comprises a poly over diffusion edge (PODE).

10. The chip of claim 1, wherein the spare cell further comprises:
a third active region, wherein the first gate extends over the third active region;
a second drain contact formed over the first active region and the third active region, wherein the second drain contact extends in the first direction.

11. The chip of claim 10, wherein the spare cell further comprises:
a second source contact formed over the first active region, wherein the first gate is between the second source contact and the second drain contact, and the second source contact is coupled to the second rail; and
a third source contact formed over the third active region, wherein the first gate is between the third source contact and the second drain contact, and the third source contact is coupled to the first rail.

12. The chip of claim 11, wherein the first active region is a p-type active region, and the third active region is an n-type active region.

13. The chip of claim 11, wherein the first rail comprises a low rail, the second rail comprises a supply rail, and the low rail has a lower potential than the supply rail.

14. A chip, comprising:
a first spare cell including:
a first active region; and
a first gate extending over the first active region in a first direction;
a second spare cell including:
a second active region; and
a second gate extending over the second active region in the first direction;
a tie cell including:
a third active region;
a third gate extending over the third active region in the first direction;
a first drain contact formed over the third active region;
a first source contact formed over the third active region, wherein the third gate is between the first drain contact and the first source contact, and the first source contact is coupled to a first rail; and
a circuit configured to couple the third gate to a second rail; and
a metal routing extending in a second direction, wherein the second direction is perpendicular to the first direction, and the first metal routing is coupled to the first drain contact, the first gate, and the second gate.

15. The chip of claim 14, wherein the first rail comprises a low rail, the second rail comprises a supply rail, and the low rail has a lower potential than the supply rail.

16. The chip of claim 14, wherein the first rail comprises a supply rail, the second rail comprises a low rail, and the low rail has a lower potential than the supply rail.

17. The chip of claim 14, wherein the metal routing is formed from a metal layer M0.

18. The chip of claim 17, wherein the metal routing comprises a metal line formed from the metal layer M0.

19. The chip of claim 17, further comprising:
a first via disposed on the first gate;
a second via disposed on the second gate; and
a third via disposed on the first drain contact, wherein the metal routing extends over the first via, the second via, and the third via.

20. The chip of claim 19, wherein the first via, the second via, and the third via are aligned in the first direction.

21. The chip of claim 14, further comprising:
a first dummy gate between the tie cell and the first spare cell, wherein the first dummy gate extends in the first direction;
a second dummy gate between the tie cell and the second spare cell, wherein the second dummy gate extends in the first direction, and the metal routing crosses over the first dummy gate and the second dummy gate.

22. The chip of claim 21, wherein the first dummy gate comprises a first poly over diffusion edge (PODE), and the second dummy gate comprises a second PODE.

23. The chip of claim 21, wherein the first spare cell and the second spare cell are located on opposite sides of the tie cell.

24. The chip of claim 14, wherein the first spare cell further comprises:
a fourth active region, wherein the first gate extends over the fourth active region;
a second drain contact formed over the first active region and the fourth active region, wherein the second drain contact extends in the first direction.

25. The chip of claim 24, wherein the first spare cell further comprises:
a second source contact formed over the first active region, wherein the first gate is between the second source contact and the second drain contact, and the second source contact is coupled to the second rail; and
a third source contact formed over the fourth active region, wherein the first gate is between the third source contact and the second drain contact, and the third source contact is coupled to the first rail.

26. The chip of claim 25, wherein the first active region is a p-type active region, and the fourth active region is an n-type active region.

27. The chip of claim 25, wherein the first rail comprises a low rail, the second rail comprises a supply rail, and the low rail has a lower potential than the supply rail.

28. A method for chip layout, comprising:
receiving a layout for a chip, wherein the layout includes a metal routing coupling an input of a spare cell to a tie cell on the chip;
determining whether to use the spare cell to implement a circuit design on a chip;
if a determination is made to use the spare cell to implement the circuit design, then inserting a cut layer in the layout for cutting the metal routing between the input of the spare cell and the tie cell.

29. The method of claim 28, further comprising, if a determination is made not to use the spare cell to implement the circuit design, then leaving the metal routing between the input of the spare cell and the tie cell unchanged.

30. The method of claim 28, wherein the metal routing is formed from a metal layer M0.
